(19) United States
(12) Patent Application Publication
(10) Pub. No.: US 2006/0268975 A1
(43) Pub. Date: Nov. 30, 2006

(54) Pulse width modulation (PWM) utilizing a randomly generated pattern subsequently modified to create desired control characteristics

(76) Inventor: Douglas A. Bors, Bellevue, WA (US)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 11/433,634

(22) Filed: May 12, 2006

Related U.S. Application Data
(60) Provisional application No. 60/681,127, filed on May 13, 2005.

(51) Int. Cl. H03K 7/08

(52) U.S. Cl. 375/238

(57) ABSTRACT

A system and method for generating a digital pulse width modulation (PWM) control signal for a power transfer device that includes providing a digital PWM signal having a stochastic characteristic, and transforming the digital PWM signal to include control information. A digital reference signal having a stochastic characteristic may be used to provide the PWM signal with stochastic characteristics, and the PWM signal is transformed so as not to lose the stochastic characteristic and stored in a digital storage device. The stored PWM signal exhibits frequency domain characteristics and is configured to minimize undesirable characteristics such as harmonic signatures, audible noise, component vibration, and frequency-domain energy peaks.

### BACKGROUND OF THE INVENTION

1. Field of the Invention

The embodiments of the invention disclosed herein relate, in general, to power transfer devices and, more particularly, to electrical power transfer devices wherein pulse width modulation is used as a control method.

2. Description of the Related Art

In applicant's prior invention, as described in U.S. Pat. No. 6,510,068, the practice in the related technical field was extended from one that utilizes deterministic waveforms to one where practitioners could utilize random waveforms or utilize deterministic signals where elements of those signals had been randomized (shifted) so that specific time domain signatures could be eliminated (or reduced) in resulting PWM control schemes. This holds promise for increased efficiencies in many classes of devices and to increased reliability in these same devices.

### BRIEF SUMMARY OF THE INVENTION

The disclosed embodiments of the invention are directed to any of several methods that are used with a power transfer device wherein the basic pattern for a PWM control signal is created with stochastic (random) characteristics and this signal is then modified and used to create a desired output waveform.

In accordance with one embodiment of the invention, a system and method for generating a digital pulse width modulation (PWM) control signal for a power transfer device is disclosed that includes providing a digital PWM signal having a stochastic characteristic, and transforming the digital PWM signal to include control information.

In accordance with another aspect of the foregoing embodiment, the stored PWM signal exhibits frequency domain characteristics of distributing one or more discrete frequency component energy among two or more discrete frequency components, distributing one or more discrete frequency component energy across portions of the continuous spectrum, distributing one or more peak densities of frequency energy from narrow segments of the continuous spectrum to wider segments of the continuous spectrum, redistributing frequency energy to segments of the frequency spectrum avoiding those portions of the spectrum that are associated with problems for power transfer devices, redistributing frequency energy and reshaping the final output waveform to intentionally compensate for pre-defined or desired harmonic components that are associated with desirable output characteristics for power transfer devices.

In accordance with another aspect of the foregoing embodiment, the stored PWM signal is configured to minimize at least one parameter from among harmonic signatures, is configured to minimize audible noise from the power transfer device, is configured to minimize component vibration in the power transfer device, is configured to reduce unnecessary switching events, is configured to reduce audible noise in power utilization equipment connected to the power transfer device, is configured to minimize component vibration in power utilization equipment connected to the power transfer device, or is configured to reduce frequency-domain energy peaks from current components in the power transfer device.

In accordance with another embodiment of the invention, a digital reference signal having a stochastic characteristic is used to provide the PWM signal with stochastic characteristics, and the PWM signal is transformed so as not to lose the stochastic characteristic and stored in a digital storage device.

In accordance with another aspect of the foregoing embodiment, at least one additional transformation of the transformed PWM signal is performed by a digital processing system. Ideally the transformed PWM signal comprises deterministic frequency signatures and stochastic frequency signatures exhibited in the frequency domain.

In accordance with another aspect of the foregoing embodiment of the invention, the method includes inputting the reference signal into a comparator to provide the PWM signal with the stochastic characteristic. Preferably the method also includes storing the reference signal in a digital memory device prior to providing the digital PWM signal.

In accordance with another aspect of the foregoing embodiment, providing the digital reference signal includes providing the digital reference signal with at least one from among the frequency domain characteristics of distributing one or more discrete frequency component energy among two or more discrete frequency components, distributing one or more discrete frequency component energy across portions of the continuous spectrum, distributing one or more peak densities of frequency energy from narrow segments of the continuous spectrum to wider segments of the continuous spectrum, redistributing frequency energy to segments of the frequency spectrum avoiding those portions of the spectrum that are associated with problems for power transfer devices, redistributing frequency energy and reshaping the final output waveform to intentionally compensate for pre-defined or desired harmonic components that are associated with desirable output characteristics for power transfer devices.

In accordance with another aspect of the foregoing embodiment of the invention, the stored reference signal is configured to minimize at least one parameter from among harmonic signatures, is configured to minimize audible noise from the power transfer device, is configured to minimize component vibration in the power transfer device, is configured to reduce unnecessary switching events, is configured to reduce audible noise in power utilization equipment connected to the power transfer device, is configured to minimize component vibration in power utilization equipment connected to the power transfer device, or is configured to reduce frequency-domain energy peaks from current components in the power transfer device.

In accordance with another embodiment of the invention, a method of generating a digital pulse width modulation (PWM) control signal for a power transfer device that does not require feedback is disclosed that includes providing a digital reference signal having a stochastic characteristic and using the reference signal to provide a digital PWM signal with stochastic characteristics for controlling the power transfer device and without providing control information in the digital PWM signal.

In accordance with another embodiment of the invention, a circuit is provided that includes circuitry or software or a combination of both for generating a digital pulse width modulation (PWM) control signal for a power transfer device that does not require feedback that includes software or a device such as a circuit that provides a digital reference signal having a stochastic characteristic; and software or a circuit that uses the reference signal to provide a digital PWM signal with stochastic characteristics for controlling the power transfer device in which the digital PWM signal has no control information.

In accordance with another aspect of the foregoing circuit, the features described above with respect to the method are embodied in the circuit. This may be accomplished in hardware, software, firmware, or any combination of the foregoing.

Also, a method is used with a power transfer device wherein the basic PWM pattern to be used in a PWM device is modified (and can be subject to analysis) and the pattern is stored, a pattern that has or that obtains random (stochastic) characteristics, and this signal is then modified and used to create a desired output waveform.

For purposes of the description herein, stochastic as used herein includes the entire range of signal descriptions from an entirely random assignment of PWM timing events to a highly selective modification of purely deterministic PWM timing events; further including any method of creating these signals, including two examples, the first being a hand generated PWM signal (representing a waveform) that would fail to pass a mathematical test for randomness, but nevertheless blurs frequency components with respect to a standard PWM signal (representing a waveform), the second being a PWM signal or reference signal that has been selected from a collection of randomly created signals subsequently singled out and then repeated to obtain desired results.

In addition, a stochastic signal as used herein is intended to include a range of stochastic activity, ranging from the assignment of a random variable or variables to an aspect or aspects of a signal, to a hand-picked, purposeful modification of an otherwise deterministic signal so that the signal exhibits one or more random or pseudo-random characteristics.

In accordance with another embodiment of the invention, a method used with a power transfer device is disclosed wherein a reference signal is used to create a PWM control signal that exhibits stochastic characteristics so that the resulting PWM control signal can be used to create a desired output waveform.

Also, an extension to these methods is provided where a pattern for the PWM signal is used as a baseline, and a feedback signal is used to further modify the PWM signal so that the resulting modified PWM control signal that exhibits stochastic characteristics can create a desired output waveform wherein an output waveform of a power transfer device acts as if fully controlled by the feedback signal.

Also, an extension to these methods is provided where two or more patterns for the PWM signal are used as a baseline, and a feedback signal is used to further modify the PWM signal, choosing as needed between the available patterns as control circumstances demand.

Ideally, the stochastic PWM signal, the stored pattern PWM signal, and the stochastic reference signal used to create a stochastic PWM signal can be created themselves in the digital domain by programming a random number generator to inform the switching times of the source pattern. Alternately, a pattern that obtains stochastic characteristics can be created in any number of ways, stored digitally, and retrieved from memory as needed.

A further extension to these methods, where a digital control program, the stored pattern PWM signal, the interface with a power transfer device output circuit, and the interface with the power transfer device feedback circuit have all been folded into one active computer program, allows that the representation of the stored pattern PWM signal may vary over a wide range of encoded patterns to suit the programming method at hand, and further, the stored pattern PWM signal may be subject to modification by the control program in order to allow for rapid adjustments to field conditions of power transfer devices.

Preferably, the stochastic signals referenced above may be a signal that is not defined as random (i.e., will not pass tests of stochastic behavior) under mathematical rigor, but rather is a blend of deterministic and stochastic characteristics so that a useful effect of eliminating some deterministic impact within a power transfer device is obtained. For example, in one embodiment, the stochastic PWM waveforms fail to pass a formal mathematical test for randomness and the PWM waveforms exhibit mixed characteristics with deterministic frequency signatures and random frequency signatures (i.e., combinations of frequency residuals where advantage is found in reducing and not eliminating deterministic frequency components).

One method for obtaining the stochastic PWM signal, the stored pattern PWM signal, or the stochastic reference signal used to create a stochastic PWM signal, utilizes the means of obtaining a random (stochastic, shifted) PWM signal as presented in the above-referenced patent, except that rather than starting with a PWM signal that contains feedback information and subsequently shifting the PWM timing events, a “standard” PWM signal is shifted, then delivered to the adjacent system component or stored for future retrieval.

The above-referenced patent describes, in one embodiment, an analog circuit, and it indicates that a parallel embodiment is echoed in the digital domain. The embodiments of the present invention are described in the digital domain. In one case (using a random {stochastic} reference waveform) this invention can be built using a digital storage device or digital waveform generator plus an analog circuit. In other cases, an analog circuit implementation depends on a PWM waveform utilizing sloped transitions.

### BRIEF DESCRIPTION OF THE SEVERAL VIEWS OF THE DRAWINGS

The foregoing and other features and advantages of the present invention will be more readily appreciated as the same become better understood from the following detailed description when taken in conjunction with the accompanying drawings, wherein:

FIG. 1 is a high-level block diagram of a Pulse Width Modulation method formed in accordance with the present invention;

FIG. 2 is a high-level block diagram of another Pulse Width Modulation method formed in accordance with the present invention;

FIG. 3 is a high-level block diagram illustrating one embodiment of the present invention;

FIG. 4 is a high-level block diagram illustrating another embodiment of the present invention;

FIG. 5 is a high-level block diagram illustrating one example of an algorithm that modifies a stream of data values by marking and moving the transition times of switching events of a PWM control signal;

FIG. 6 is a time-domain graph depicting one example of a control signal that might be used to create a sinusoidal waveform using PWM methods previously found in the art; and one example of a control signal that has been modified by moving the transition times of switching events of the original PWM control signal;

FIG. 7 is a frequency-domain graph depicting the results of a digital Fourier transform performed on two PWM control signals; the first signal similar to the upper signal shown in FIG. 6 and the second similar in concept to the lower signal shown in FIG. 6;

FIG. 8 is a frequency-domain graph depicting the results of a digital Fourier transform performed on two control signals; the first signal based on a hand picked waveform close to a PWM control signal previously available in the art, and the second signal based on a hand coded waveform defined to accomplish specific goals related to power transfer devices; and

FIG. 9 is a high level block diagram illustrating one example of an implementation that supports an algorithm to modify or create a stream of data values by marking and moving the transition times of switching events of a PWM control signal.

### DETAILED DESCRIPTION OF THE INVENTION

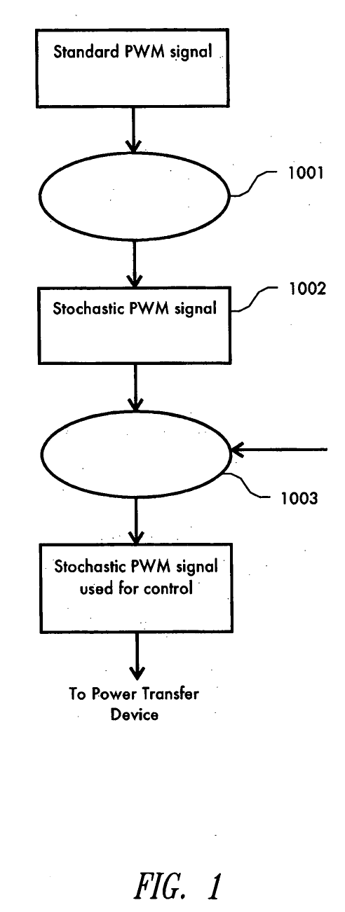

Specifically, and with reference to FIG. 1, a standard deterministic PWM signal represents the waveform it will create as a portion of turn-on-time from moment to moment. If this standard deterministic PWM waveform is passed through a process 1001 that substantially matches the process identified in U.S. Pat. No. 6,510,068, then the output from that process has the stochastic characteristic of a spread frequency signature, and if designed to meet specific parameters, the output does not exhibit the nominal frequency signature (or the output exhibits reduced components of its nominal frequency signature) associated with the standard deterministic PWM signal. This output stochastic PWM signal 1002 may be stored. This output is then used to drive a switching section of a power transfer device, or if additional feedback information is required, this output is passed through a process 1003 that incrementally adds the feedback information to the signal and is subsequently used to drive a switching section of a power transfer device.

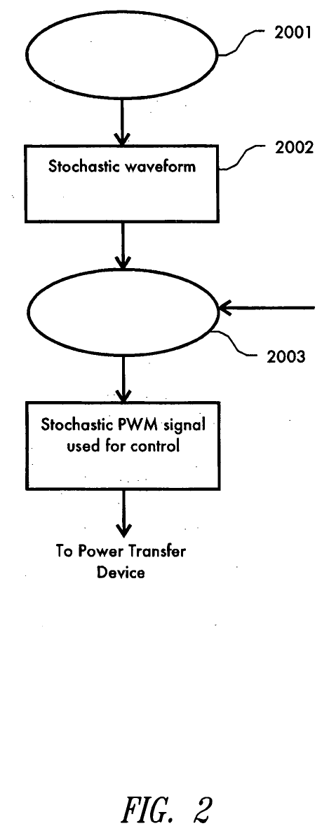

In an additional method, generally available in both the analog and digital domain, a signal in FIG. 2 is created via a process 2001 selected from various processes including, hand picking switching times for a PWM waveform, hand picking state values for a PWM, hand picking a sawtooth waveform shape, creating numerous patterns using pseudo-random trials and selecting the most successful pattern, creating a transform of a standard PWM waveform and modifying that transform, subsequently recreating the PWM waveform via a second transform, etc. This stochastic waveform 2002 may be stored. This signal is further processed in a process step 2003 that may include a comparator circuit, or any of several other means of incrementally including feedback information into a final stochastic PWM signal used for control. In the analog domain, this method, for example, is used to create a PWM control signal as shown in FIG. 2, by creating a reference waveform in process 2001 and passing an image of a desired output waveform past a reference sawtooth waveform in a comparator circuit. In this example, a stochastic reference sawtooth waveform is used as the basis for comparison in process step 2003 and the resulting PWM control signal exhibits stochastic characteristics. If the original reference sawtooth waveform is defined based on specific frequency domain parameters, then the resulting PWM control signal will exhibit specific (desirable) frequency characteristics.

The disclosed embodiments of the present invention involve the use of a stochastic reference signal based on a PWM pattern, or a stochastic reference waveform used to create a stochastic PWM waveform, which is subsequently used, in some cases after further modification, to carry control information and, in some cases without further modification, to control a power transfer device.

Power transfer devices are, in some cases, made to control single-phase power flow; in this case the invention is substantially represented as a single PWM control signal stream. In other cases, power transfer devices are made to control two- or three-phase power flow, and in a few cases, power transfer devices control power flow in many pathways (e.g., six or twelve in harmonic power mitigation systems); in these cases the invention is substantially represented as one or more PWM control signal streams.

The disclosed embodiments of the present invention are operable in the digital domain, where signals are represented as streams of values that reflect time domain waveforms, in the digital domain where signals are represented as streams of values that reflect frequency (or wavelet) domain information, and in the analog domain where signals are represented as varying voltages that reflect time domain waveforms.

The following descriptions, coordinated with block diagrams of the method, are related to the digital domain. The implementation in the analog domain is accessible to practitioners of the art by extending the waveform descriptions (in cases where an analog waveform is plausible) from the digital domain to the analog domain.

There are several ways that this invention can be embodied to accomplish the same effect. Two are outlined herein. As will be readily appreciated from following description, the general order of the process and the resulting effect are among the novel characteristics of the invention.

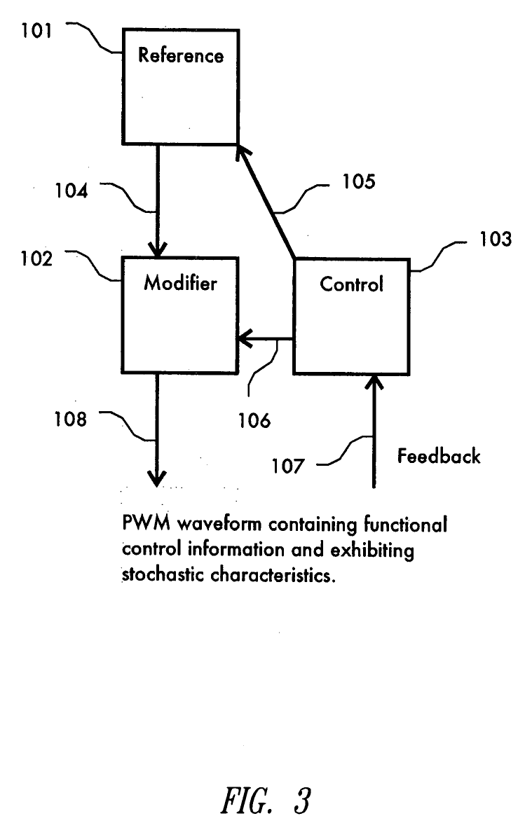

Referring to FIG. 3, shown therein is a three block method comprised of a block 101 that generates a reference, a block 103 that is the interface between one or more feedback signals and the desired control (including the special case where control is generated without a feedback signal), and a block 102 that accepts the desired control signal and uses its composite information to modify the reference signal to create the desired output signal—a PWM waveform containing functional control information exhibiting stochastic characteristics.

The reference block 101 creates a PWM signal that exhibits stochastic characteristics. It may do this via several means. For example, it may create a standard PWM signal based on a sine wave function of a digital processor and run that standard PWM signal through a shifting method like the method of the reference U.S. Pat. No. 6,510,068. Or, for example, it may index a series of stored digital values that represent a PWM signal that exhibits stochastic characteristics and set this series of values on the output channel. The reference block 101 serves one outbound interface 104 that substantially represents a signal path to the modifier block 102. The reference block accepts an inbound interface 105 that substantially represents the timing of the PWM signal. The interface 105 that substantially represents the timing of the PWM signal may be implemented as an indexed lookup of stored digital values representing a signal.

The control block 103 manages or translates a feedback signal so that desired control components (e.g., timing and amplitude) are identified by its outbound interfaces 105, 106. This control signal management is highly dependent on the application and specific characteristics of power switching elements and load characteristics of the power transfer device. Further, this control management is readily understood and executed by practitioners skilled in the art. The resulting outbound interface 105, 106 streams may be defined to represent any of several control functions. For example, they might represent synchronization (i.e., the timing of the desired power transfer device output waveform) and amplitude (i.e., the equivalent voltage level of the desired power transfer device output waveform). The resulting outbound interface 105, 106 streams may be defined to represent other combinations of control functions.

The modifier block 102 is the locus of power management within the context of this block diagram. The modifier block has two inbound interfaces, one for a reference signal 104 and another for control information 106. The modifier block utilizes information from these two inbound interfaces to establish an outbound stream and deliver it to one or more outbound interfaces 108 that eventually exert control over power switching components in a power transfer device.

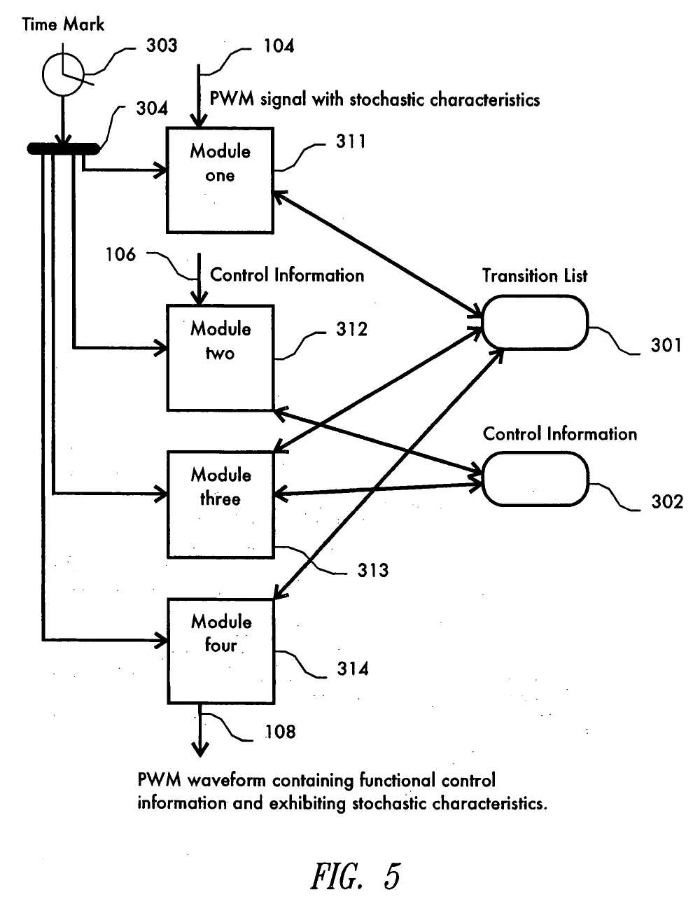

The modifier block 102 may operate in the digital domain in many specific ways. In general the modifier block follows an algorithm to add control information to the reference waveform while protecting the stochastic characteristics of the reference waveform. In one case, the case of varying the amplitude of the PWM control signal (i.e., varying the equivalent voltage level of the desired power transfer device output waveform) the algorithm modifies a stream of data values by marking and moving the transition times of switching events of the PWM control signal. For example, a functional code outline might look like the diagram shown in FIG. 5 and be described as follows:

Time Mark 303: In this example, each time mark is characterized as an index that counts fixed width time segments. The time mark 303 creates a timing event that is delivered to each program module via a synchronization bus 304. In other implementations of this invention, the time mark may be based on variable width segments that are scaled to facilitate frequency control or phase adjustment of the fundamental output waveform of a power transfer device.

Module one 311: At each time mark, note and store the value of the inbound interface 104 PWM control signal. When the value is the same as the value at the last time mark, do nothing. When the value changes, save the new value in a local register and save the current time mark in a transition list 301. Share this transition list 301 with modules three and four.

Module two 312: At each time mark, note and store the value of the inbound interface 106 control signal and scale this value as a basis for adding (or removing) “on” time to (from) the PWM control signal. Share this control information 302 with module three.

Module three 313: At each time mark, check the list of transitions in the transition list 301 shared by module one and check the basis for adding (or removing) “on” time in control information 302 shared by module two. Use the second value to delay the “off” switching event at off transitions (or to delay the “on” switching event at on transitions, or both) and replace this specific off event saved by module one in the transition list with a new value. Also, check for cases where there is insufficient time for added “on” time due to the occurrence of an upward switching event (or insufficient time for reduced “on” time due to the occurrence of a downward switching event) prior to the new transition time required to increase (or decrease) “on” time. This occurs because the reference PWM waveform exhibits stochastic characteristics and the timing events may be relatively smaller than the desired change in transition time. In this case, save the excess delay for the next appropriate transition.

Module four 314: At each timing mark, check the list of transitions in the transition list 301 shared by module one and modified by module three. If a transition is indicated at this timing mark (by the existence of a timing mark in the list that matches the current timing mark), execute the transition by changing the value of the PWM waveform that is recreated for the outbound interface 108 and remove the timing mark from the transition list 301. If a transition is not indicated at this timing mark, maintain the value of the PWM waveform that is recreated for the outbound interface 108 at its previous value and make no changes to the transition list 301.

The modifier block 102 in the diagram in FIG. 3 is readily implemented by practitioners familiar with the art and will not be described in greater detail herein. For example, the computer code outline described above is a matter of managing power flow represented by the feedback and control signals. The computer code outline is unusual only because it is not needed in applications extent in power transfer devices. As is readily appreciated from the forgoing description, the combination of a stochastic reference with a meaningful control signal is among the novel characteristics of the present invention.

Based on this, or any other similar algorithm, the modifier block recreates, shifts, or leaves unchanged a signal that appears on the outbound interface 108, thus creating a PWM waveform containing functional control information and exhibiting stochastic characteristics.

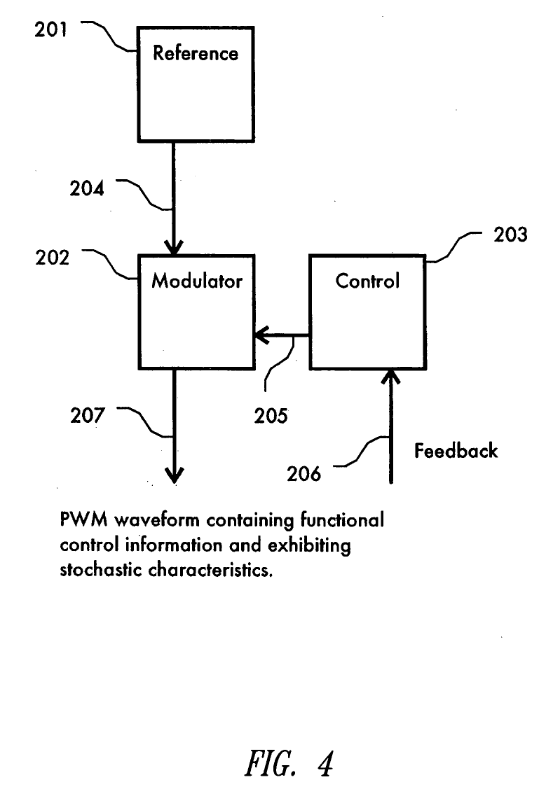

A further embodiment is described in conjunction with FIG. 4 as a three block method that includes a block 201 that generates a reference, a block 203 that is the interface between a feedback signal and the desired control (including the special case where control is generated without a feedback signal), and a block 202 that accepts the desired control signal and uses its component information to create a PWM waveform containing functional control information exhibiting stochastic characteristics.

The reference block 201 creates a reference waveform (e.g., a reference waveform that can be used in a comparator circuit to trigger a PWM waveform). This reference waveform may be any of several formats. For example, it may be a pair of sawtooth waveforms established for the positive and negative polarities of a comparator module, it may be a triangle waveform used for the same purpose, it may be a truncated triangle waveform, it may be a triangle waveform with curvilinear edges (as plotted in the time domain) in order to help create non-linear signals to compensate for non-linear load characteristics, etc. The reference waveform is created so that the timing of one or more slopes, and thus the timing between repeated elements of the waveform (e.g., between subsequent peaks or alternate peaks), is stochastic. The reference block 201 may create this waveform by advancing an index and retrieving a value from a series of values that have been previously stored. The reference block creates a signal stream to represent a signal on an outbound interface 204.

The control block 203 functions to manage or translate a feedback signal to make it useful for control. In this block diagram, the control block 203 acts to create an image (or representative) signal stream that reflects the intended control outcome. This signal is set on the outbound interface 205 as information for the modulator block 202.

The modulator block 202 in this block diagram may use an inbound interface 204 to control the formation of one or more outbound interface signals by any of several means. For example, if the inbound interface is a stream representing a sawtooth waveform, the modulator may compare the value of the second inbound interface 205 to the value of the first inbound interface 204 and choose an output value from a table based on which of the two compared values is higher.

The modulator block 202 in this diagram is not unusual in the art; for example, the example in the paragraph above is representative of a common method for creating a PWM waveform from a reference control signal in the analog domain. As is readily appreciated from the forgoing description, the combination of a stochastic source with a meaningful control signal is among the novel characteristics of the present invention.

The modulator block 202 sets the values created as described above on the outbound interface 207, thus creating a PWM waveform containing functional control information and exhibiting stochastic characteristics.

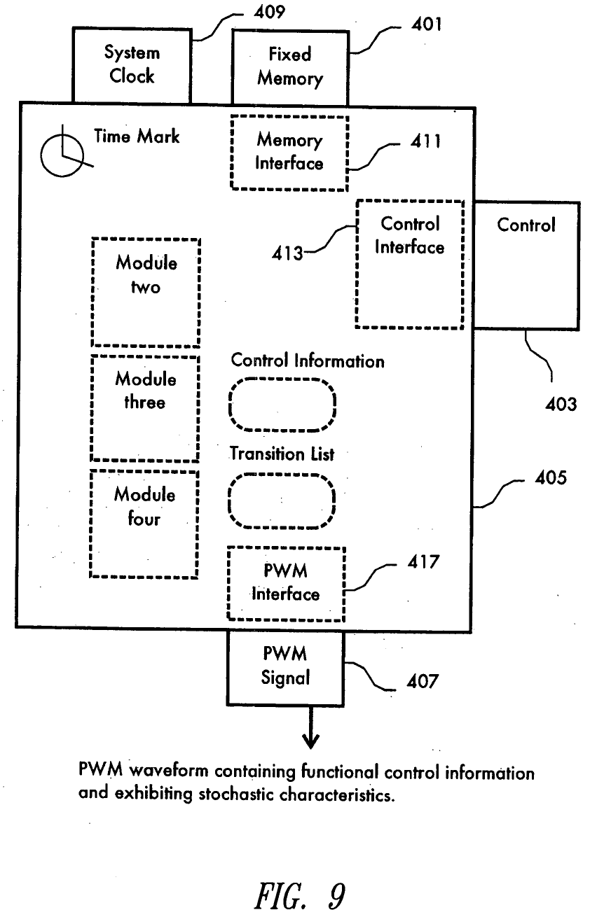

For purposes of clarity, the descriptions of the embodiments above utilize separate program modules to indicate sub-functions of the invention. In practice, the codification of these embodiments (e.g., a specific implementation in a programming language) is compact enough that it can be represented in a single algorithmic definition several pages in length. This allows one to conceptualize the implementation as a more compact, more closely integrated, program. This is further demonstrated in FIG. 9; where several elements found in FIG. 5 have been reorganized within one digitally implemented computer program block 405. Specifically, module two, module three, module four, a control information register or registers, and a transition list register or registers may all carry similar purpose from FIG. 5 to FIG. 9. In this implementation example, fixed memory block 401 represents physical stored memory, implying that the memory interface block 411 is an active component of program block 405. Similarly, control interface block 413, providing information transfer from physical control circuits 403 to program block 405, the time mark, providing information transfer from system clock 409 to program block 405, and PWM interface block 417, providing information transfer from program block 405 to PWM Signal circuitry 407, are active components of program block 405.

Conceptualizing the implementation as a more closely integrated program holds several implications for practitioners of the art. First, the means of encoding a PWM signal with stochastic characteristics for storage may include one or more of several options, including, for example, a list of state values (i.e., a value describing whether a pulse is on {as either a positive or negative pulse} or off), or a list of transition times. Second, a program block 405 may be implemented to maintain an entire pattern for a PWM signal with stochastic characteristics in active memory, precluding the need for the function of module one (reference FIG. 5). Third, a program block 405 may be implemented to modify portions of an entire pattern of a PWM signal with stochastic characteristics in active memory, rendering an additional degree of control (for example, scaling an entire pattern, or shifting an entire pattern) to adjust for circumstances of a power transfer device. Fourth, a program block 405 may be implemented to include multiple patterns for PWM signals with stochastic characteristics, each designed for a different circumstance, to facilitate selection of one of these patterns to best match the circumstances of the power transfer device by the program block 405. Fifth, a program block 405 may be implemented to include each phase and each output segment of a power transfer controller in order to complete required control functions (for example, in order to manage the balance of positive and negative portions of a sinusoidal waveform, or in order to manage the balance between phases in a multi-phase power transfer device).

The form of the invention and the characteristics of control following from the invention are related, in addition to other components of the invention, to characteristics of any one of several possible comparative waveforms that are designed to optimize multiple parameters of power transfer waveforms so that a final power transfer waveform created by a PWM signal is optimized for use in a power transfer application. A comparative waveform is a pattern that has been developed, or partially developed, and stored with the specific purpose of minimizing harmonic signatures, minimizing perceived audio components, minimizing vibration, enhancing power transfer, and creating a predictable and reliable waveform.

The creation, temporary storage, analysis, tuning, and final storage of a series of comparative waveforms, ultimately resulting in a best signal model (aka signal replica) is one result and a benefit of the invention described herein.

A fully developed comparative waveform (stored as a signal replica) would, for example, appear as the signal delivered by Module 101 in FIG. 3 or the as the signal delivered by Module 201 in FIG. 4.

In accordance with another aspect of the invention one characteristic of control is enhanced by minimizing the processing time required for feedback control signals by segregating the creation (or storage and retrieval) of a comparative waveform (aka signal replica) from the operations on the comparative waveform required by the feedback signal. For example, the interaction of Module 3 in FIG. 5 with the transition list 301 only requires computational time (which can be very short relative to 60 hertz systems) plus an intentional delay to allow a PWM signal time to scale the width of each pulse. To further this example, the retrieved PWM waveform may be “advanced” relative to the intended output waveform, using the feedback control to make adjustments based on the just-previous value of the control Information. This allows the PWM output to track to as short a time as the time between one or two time slices of the waveform, while embodying a delay in responsiveness of the control signal of only several time slices. To further this example, the program block 405 in FIG. 9, using a closely integrated program, can further reduce the time delay between changes in control requirements and changes in the PWM waveform.

In accordance with a further aspect of the invention, the quality of power transfer device output is enhanced by allowing the comparative waveform to undergo frequency domain analysis, power spectrum analysis, impulse analysis, resonance analysis, or wavelet component analysis, whichever are most appropriate to a specific power transfer device.

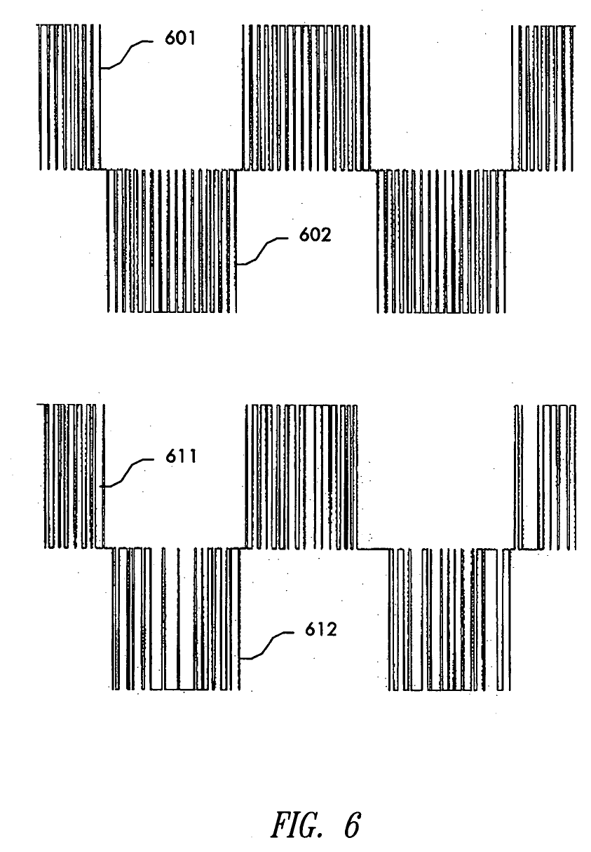

For example, FIG. 6 depicts two time-domain graphs showing two distinct PWM control waveforms; the upper control waveform is representative of a PWM waveform generated by previous methods, and the lower control waveform is a PWM waveform that has been modified by varying the switching event timing. The upper control waveform shows an upper portion 601 of each sinusoidal waveform as a series of 17 pulses on the positive half-cycle and shows a lower portion 602 of each sinusoidal waveform as a series of 17 negative pulses on the negative half-cycle. The lower waveform shows an upper portion 611 of each sinusoidal waveform as a series of approximately (but not consistently) 17 pulses on the positive half-cycle and shows a lower portion 612 of each sinusoidal waveform as a series of approximately (but not consistently) 17 negative pulses on the negative half-cycle. The graph depicts a portion of a control waveform required to create approximately two cycles of cosine waveform in the output of a power transfer device. In practice, the upper and lower portions of a power waveform are often produced through two distinct pathways of circuiting in a power transfer device; this requires one or more separate control waveforms for each pathway of power circuiting. The control waveform is depicted here as one waveform to facilitate frequency domain analysis. The graph depicts the use of 17 pulses to create each half-cycle; in practice the number of pulses used varies and is often greater. The waveform is depicted here with 17 pulses in each half-cycle because it exaggerates the problems depicted in the frequency domain analysis. In this example, the lower control waveform is created by taking the upper waveform and applying a random delay to each of the control signal transitions (i.e., to each change from on to off or from off to on). In this process of creating the lower waveform, pulses occasionally overlap, thereby eliminating a pair of transitions; thus, the lower control waveform does not show a consistent pulse count.

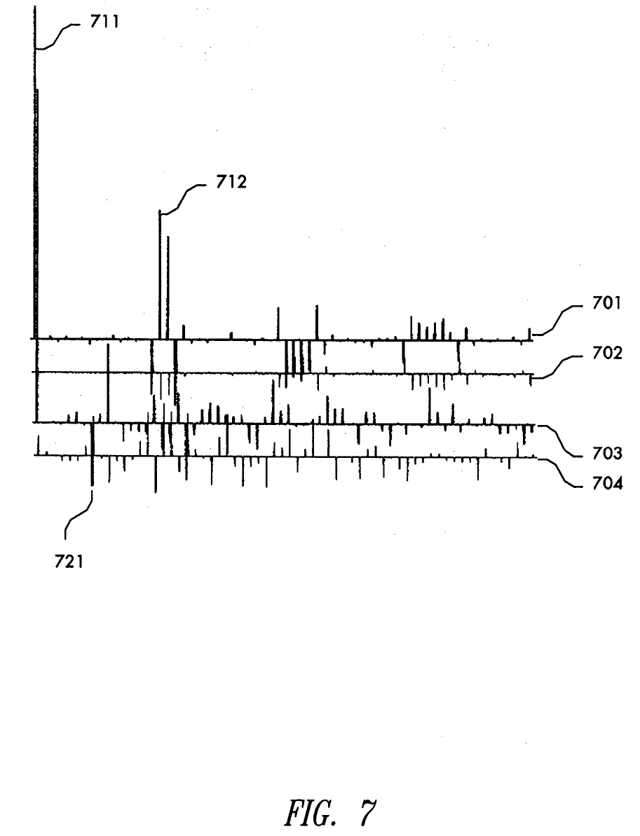

Continuing the example, FIG. 7 depicts four frequency-domain graphs showing the approximate arrangement of frequency components related to the control waveforms in FIG. 6. The top trace 701 represents the real component of the upper control waveform from FIG. 6. The top trace is scaled by its fundamental frequency value 711. Each trace is scaled vertically to match the scale of the top trace. Each trace is scaled horizontally to show frequency components beginning with the fundamental frequency and extending through approximately the 64^{th} harmonic. The traces are offset slightly horizontally to allow large harmonic values to pass beyond an adjacent graph and still be seen. The 17^{th} harmonic 712 is depicted as the most significant harmonic after the fundamental for the upper control waveform in FIG. 6. The second trace from the top 702 represents the imaginary component of the upper control waveform from FIG. 6. The third trace from the top 703 represents approximately the real component of the lower control waveform in FIG. 6. The bottom trace 704 represents approximately the imaginary component of the lower control waveform in FIG. 6. Each trace is based on a digital Fourier transform of eight cycles, each cycle with identical control waveform transition times. Each control waveform is established using a clock based on 2048 segments per cycle. In practice, clock divisions can be based on a wide range of values including 2048 segments per cycle. The purpose of holding an analysis across eight cycles (and of repeating each cycle with identical control waveform transition times) is to exaggerate the graphic indication of frequency components in the control waveform to be tested.

To extend this example further, the second control waveform in FIG. 6 was selected from over twenty sets of delay patterns. The code fragment below represents the delay pattern applied to the original PWM control waveform. This delay pattern is repeated each half-cycle. The delay pattern includes 17 pairs of numbers, each pair applied to the pair of turn-on and turn-off transitions that make one pulse in the control signal.
;hand selected pattern number 14
(define random-delay-source-list
‘(9 9 11 11 1 1 19 19 6 6 14 14 9 9 11 11 10 10 11 11 9 9 14 14 6 6 19 19 1 1 12 12 8 8))

The code fragment above is based on the Scheme dialect of Lisp. The fragment indicates the assignment of delay values (represented in clock segments). Scheme is used here to demonstrate values for this example; in practice any one of many programming languages are used to define control waveforms and to accomplish waveform analysis.

To complete the example started above, the list of delay values was selected from over twenty lists that were designed to meet specific goals. Even so, the frequency-domain graph in FIG. 7 representing the resulting control waveform includes considerable energy in the 8^{th} harmonic 721 and in the 10^{th} harmonic. In practice, energy included in lower harmonics of power transfer devices is undesirable.

In one implementation, the present invention reduces residual harmonic components by facilitating hand-selected bits to be added or removed from a stored comparative waveform, in effect modifying the transition times of one comparative waveform to create a modified comparative waveform. Hand-selecting bits can include adding and removing bits to match specific targets of voltage or energy part sums based on normalized power transfer algorithms. In another aspect of the implementation, hand-selecting bits includes adding and removing bits to match specific targets of frequency domain or power spectrum part sums based on sophisticated power transfer algorithms. Sophisticated power transfer algorithms include, among other possible implementations, a displacement algorithm wherein one or more individual pulse(s) is (are) moved in time and then adjusted in duration to minimize the impact on lower numbered harmonics. And in accordance with a further aspect of the implementation, hand-selecting bits includes trading bits across spectrum locations based on balancing multiple functional tradeoffs in power transfer waveforms. The present invention provides the ability to enhance the design of power transfer waveforms through, among other features, the ability to concurrently define both shifts in timing and shifts in duration of PWM pulses in creating comparative waveforms. In other words, the PWM waveform is modified by shifting the timing and by altering the duration of the pulse at the same time.

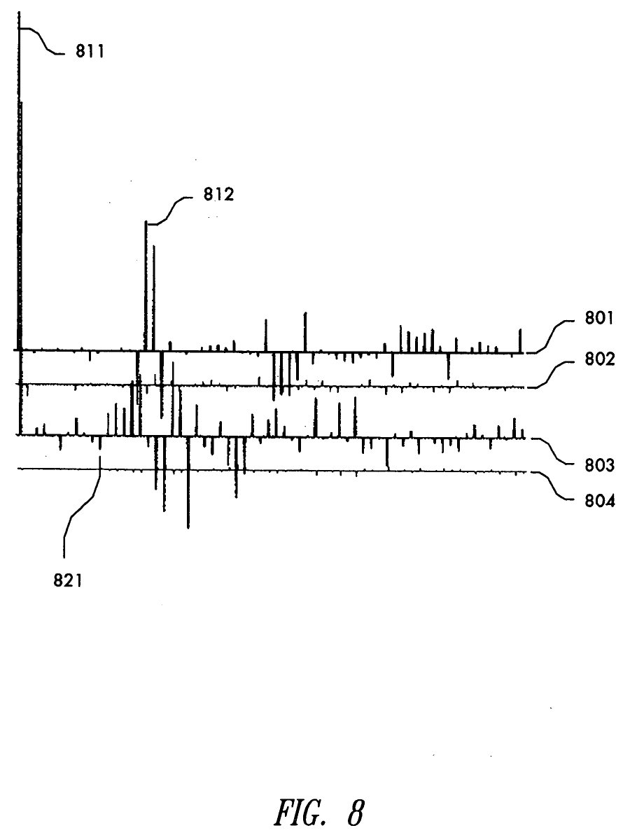

For example; FIG. 8 depicts four frequency-domain graphs showing the approximate arrangement of frequency components related to control waveforms similar to the control waveforms shown in FIG. 6, except the waveform representations used here were develop entirely by hand. The top trace 801 represents the real component of a basic control waveform. The top trace is scaled by its fundamental frequency value 811. Each trace is scaled vertically to match the scale of the top trace. Each trace is scaled horizontally to show frequency components beginning with the fundamental frequency and extending through approximately the 64^{th} harmonic. The traces are offset slightly horizontally to allow large harmonic values to pass beyond an adjacent graph and still be seen. The 17^{th} harmonic 812 is depicted as the most significant harmonic after the fundamental for the basic control waveform. The second trace from the top 802 represents the imaginary component of the basic control waveform. The third trace from the top 803 represents approximately the real component of a modified control waveform. The bottom trace 804 represents approximately the imaginary component of the modified control waveform. Each trace is based on a digital Fourier transform of eight cycles, each cycle with identical control waveform transition times. Each control waveform is established using a clock based on 2048 segments per cycle.

Continuing this example; the basic control waveform is defined using a collection of state values (i.e., a value describing whether a pulse is on {as either a positive or negative pulse} or off) as listed below; with 1 representing ‘on’ and 0 representing ‘off’.

```
(define about-eight-cycles-basic-control-waveform
  (lambda ( )
  (let ((list-of-values ‘( ))
    (seed-list-1
      ‘(0 0 0 0 0 0 0 0 0 0 0 0 0 0 0 0 0 0 0 0 0 0 0 0 0 0 0 0 0 1 1
      0 0 0 0 0 0 0 0 0 0 0 0 0 0 0 0 0 0 0 0 0 0 0 0 0 0 0 0 0 0
      0 0 0 0 0 0 0 0 0 0 0 0 0 0 0 0 0 0 0 0 0 0 0 0 0 1 1 1 1 1
      1 1 1 1 1 0 0 0 0 0 0 0 0 0 0 0 0 0 0 0 0 0 0 0 0 0 0 0 0 0
      0 0 0 0 0 0 0 0 0 0 0 0 0 0 0 0 0 0 0 1 1 1 1 1 1 1 1 1 1 1
      1 1 1 1 1 1 1 1 1 1 0 0 0 0 0 0 0 0 0 0 0 0 0 0 0 0 0 0 0 0
      0 0 0 0 0 0 0 0 0 0 0 0 0 0 0 1 1 1 1 1 1 1 1 1 1 1 1 1 1 1
      1 1 1 1 1 1 1 1 1 1 1 1 1 1 1 0 0 0 0 0 0 0 0 0 0 0 0 0 0 0
      0 0 0 0 0 0 0 0 0 0 0 1 1 1 1 1 1 1 1 1 1 1 1 1 1 1 1 1 1 1 1
      1 1 1 1 1 1 1 1 1 1 1 1 1 1 1 1 1 1 0 0 0 0 0 0 0 0 0 0 0 0
      0 0 0 0 0 0 0 0 1 1 1 1 1 1 1 1 1 1 1 1 1 1 1 1 1 1 1 1 1 1
      1 1 1 1 1 1 1 1 1 1 1 1 1 1 1 1 1 1 1 1 1 1 1 1 0 0 0 0 0 0
      0 0 0 0 0 0 0 1 1 1 1 1 1 1 1 1 1 1 1 1 1 1 1 1 1 1 1 1 1 1
      1 1 1 1 1 1 1 1 1 1 1 1 1 1 1 1 1 1 1 1 1 1 0 0 0 0 0 0 0 0
      0 0 0 0 1 1 1 1 1 1 1 1 1 1 1 1 1 1 1 1 1 1 1 1 1 1 1 1 1 1
      1 1 1 1 1 1 1 1 1 1 1 1 1 1 1 1 1 1 1 1 1 1 1 1 1 1 1 0 0 0
      0 0 0 0 0 0 1 1 1 1 1 1 1 1 1 1 1 1 1 1 1 1 1 1 1 1 1 1 1 1
      )
      )
    (seed-list-2
    ‘(1 1 1 1 1 1 1 1 1 1 1 1 1 1 1 1 1 1 1 1 1 1 1 1 0 0 0 0 0 0 0
      0 0 0 0 1 1 1 1 1 1 1 1 1 1 1 1 1 1 1 1 1 1 1 1 1 1 1 1 1 1
      1 1 1 1 1 1 1 1 1 1 1 1 1 1 1 1 1 1 1 1 1 1 1 1 1 0 0 0 0 0
      0 0 0 0 0 0 0 0 1 1 1 1 1 1 1 1 1 1 1 1 1 1 1 1 1 1 1 1 1 1
      1 1 1 1 1 1 1 1 1 1 1 1 1 1 1 1 1 1 1 1 1 1 1 1 0 0 0 0 0 0
      0 0 0 0 0 0 0 0 0 0 1 1 1 1 1 1 1 1 1 1 1 1 1 1 1 1 1 1 1 1
      1 1 1 1 1 1 1 1 1 1 1 1 1 1 1 1 1 1 1 1 1 0 0 0 0 0 0 0 0 0
      0 0 0 0 0 0 0 0 0 0 0 0 1 1 1 1 1 1 1 1 1 1 1 1 1 1 1 1 1 1
      1 1 1 1 1 1 1 1 1 1 1 1 1 1 1 1 1 1 1 1 0 0 0 0 0 0 0 0 0 0 0
      0 0 0 0 0 0 0 0 0 0 0 0 0 0 0 1 1 1 1 1 1 1 1 1 1 1 1 1 1 1
      1 1 1 1 1 1 1 1 1 1 1 1 1 1 0 0 0 0 0 0 0 0 0 0 0 0 0 0 0 0
      0 0 0 0 0 0 0 0 0 0 0 0 0 0 0 0 0 0 1 1 1 1 1 1 1 1 1 1 1 1
      1 1 1 1 1 1 1 1 1 1 1 1 1 0 0 0 0 0 0 0 0 0 0 0 0 0 0 0 0 0
      0 0 0 0 0 0 0 0 0 0 0 0 0 0 0 0 0 0 0 0 0 0 0 1 1 1 1 1 1 1
      1 1 1 1 1 1 1 0 0 0 0 0 0 0 0 0 0 0 0 0 0 0 0 0 0 0 0 0 0 0
      0 0 0 0 0 0 0 0 0 0 0 0 0 0 0 0 0 0 0 0 0 0 0 0 0 0 0 1 1 1
      1 1 1 1 1 0 0 0 0 0 0 0 0 0 0 0 0 0 0 0 0 0 0 0 0 0 0 0 0 0
      )
      ))
  (do
    ((number-of-cycles 0 (+ 1 number-of-cycles)))
    ((> number-of-cycles 7) list-of-values)
    (begin
    (set! list-of-values (append list-of-values seed-list-2))
    (set! list-of-values (append list-of-values (trade-values seed-list-1)))
    (set! list-of-values (append list-of-values (trade-values seed-list-2))))
    (set! list-of-values (append list-of-values seed-list-1))
    )
  )))
```

The code fragment above is based on the Scheme dialect of Lisp. The fragment indicates the assignment of state values to create a list representing a basic control waveform. Scheme is used here to demonstrate values for this example; in practice any one of many programming languages are used to define control waveforms and to accomplish waveform analysis. In the fragment above, the program-defined function named “(trade-values<seed-list>)” is used to assign a value of “−1” in the place of each value “1” as needed to represent the negative half-cycle of sinusoidal waveforms with a PWM control signal.

Continuing this example, each string of 1's in a row represent one pulse and operations on these pulses occur by transitioning pulse-edge 0's to 1's or pulse-edge 1's to 0's in order to widen or narrow each pulse respectively. This basic pattern is nearly the same pattern as would be obtained by mathematically creating a theoretical cosine wave using previous art PWM methods.

Continuing this example, similar to the definition of the basic control waveform, the modified control waveform is defined using a collection of state values (i.e., a value describing whether a pulse is on {as either a positive or negative pulse} or off) as listed below; with 1 representing ‘on’ and 0 representing ‘off’.

```
(define about-eight-cycles-modified-control-waveform
  (lambda ( )
  (let ((list-of-values ‘( ))
    (seed-list
      ‘(0 0 0 0 0 0 0 0 0 0 0 0 0 0 0 0 0 0 0 0 0 0 0 0 0 0 0 0 0 0 0
      0 0 0 0 0 0 0 0 0 0 0 0 0 0 0 0 0 0 0 0 0 0 1 1 1 1 1 1 1 0
      0 0 0 0 0 0 0 0 0 0 0 0 0 0 0 0 0 0 0 0 0 0 0 0 0 0 0 0 0 0
      0 0 0 0 0 1 1 1 1 1 1 1 1 1 1 1 1 1 0 0 0 0 0 0 0 0 0 0 0 0
      0 0 0 0 0 0 0 0 0 0 0 0 0 0 0 0 0 0 0 0 0 0 0 0 0 1 1 1 1 1
      1 1 1 1 1 1 1 1 1 1 1 1 0 0 0 0 0 0 0 0 0 0 0 0 0 0 0 0 0 0
      0 0 0 0 0 0 0 1 1 1 1 1 1 1 1 1 1 1 1 1 1 1 1 1 1 1 1 1 1 0
      0 0 0 0 0 0 0 0 0 0 0 0 0 0 0 0 0 0 0 0 0 1 1 1 1 1 1 1 1 1
      1 1 1 1 1 1 1 1 1 1 1 1 1 1 1 1 1 1 1 1 1 1 1 1 1 1 1 1 1 0 0
      0 0 0 0 0 0 0 0 0 0 0 0 0 0 0 0 0 0 0 0 1 1 1 1 1 1 1 1 1 1
      1 1 1 1 1 1 1 1 1 1 1 1 1 1 1 1 1 1 1 0 0 0 0 0 0 0 0 0 0 0
      0 0 0 0 0 0 0 0 0 0 1 1 1 1 1 1 1 1 1 1 1 1 1 1 1 1 1 1 1 1
      1 1 1 1 1 1 1 1 1 1 1 1 1 1 1 1 1 1 1 1 1 1 1 1 1 1 1 1 1 0
      0 0 0 0 0 0 0 0 0 0 0 0 0 0 0 1 1 1 1 1 1 1 1 1 1 1 1 1 1 1
      1 1 1 1 1 1 1 1 1 1 1 1 1 1 1 1 1 1 1 1 1 1 1 1 1 1 1 1 1 1
      1 1 1 1 1 1 1 1 1 1 1 1 1 0 0 0 0 0 0 0 0 0 0 0 0 0 1 1 1 1
      1 1 1 1 1 1 1 1 1 1 1 1 1 1 1 1 1 1 1 1 1 1 1 1 1 1 1 1 1 1
      )
      ))
  (do
    ((number-of-cycles 0 (+ 1 number-of-cycles)))
    ((> number-of-cycles 7) list-of-values)
    (begin
    (set! list-of-values (append list-of-values (reverse seed-list)))
    (set! list-of-values (append list-of-values (trade-values seed-list)))
    (set! list-of-values (append list-of-values (trade-values (reverse seed-
list)))))
    (set! list-of-values (append list-of-values seed-list))
    )
  )))
```

The code fragment above is based on the Scheme dialect of Lisp. The fragment indicates the assignment of state values to create a list representing a modified control waveform. Scheme is used here to demonstrate values for this example; in practice any one of many programming languages are used to define control waveforms and to accomplish waveform analysis. In the fragment above, the program-defined function named “(trade-values<seed-list>)” is used to assign a value of “−1” in the place of each value “1” as needed to represent the negative half-cycle of sinusoidal waveforms with a PWM control signal.

Continuing this example, each string of 1's in a row represent one pulse and operations on these pulses occur by transitioning pulse-edge 0's to 1's or pulse-edge 1's to 0's in order to widen or narrow each pulse respectively. This modified pattern would not be obtained by mathematically creating a theoretical cosine wave using previous art PWM methods; instead, it is created by hand placing state values in order to create desired results that are consistent with power transfer device operation. In this particular example, the goals set out for the modified control waveform included reduction of the 3^{rd}, 5^{th}, 7^{th}, and 9^{th} harmonic components, and the reduction of the 17^{th} harmonic component, similar to the 17^{th} harmonic component 812 that is prominent in the frequency-domain analysis of the basic control waveform. Further, both the pulses and the spaces between pulses are defined to consistently respect a minimum number of state slots (seven) so as to allow for a range of future control feedback with minimum impact on control signal characteristics.

Finally, the modified control waveform is developed using 17 pulses in each half-cycle, identical to the basic control waveform shown in this example. In FIG. 8, both the real component represented by the third trace from the top 803 and the imaginary component represented by the bottom trace 804 are substantially free of harmonic components up to and including the 11^{th} harmonic and the 17^{th} harmonic is substantially eliminated. Instead, other harmonic components are prevalent. In practice, it is a matter of many trade-offs between PWM frequency, harmonic component values, and control scheme selection; but this example demonstrates both the ability to analyze a stored waveform so as to modify that waveform to match specific goals, and the ability to modify the way frequency components are allocated through the variation of both pulse location and width.

Although the example above demonstrates the utilization of fixed width state slots (e.g., 2048 slots per cycle) and the ability to reserve a fixed number of state slots to facilitate control, in another implementation of the invention the control scheme may utilize a continuously variable adjustment to pulse widths that are otherwise stored as fixed width state slots.

In another implementation of the invention the state slots may be modified in real time to make adjustments of the fundamental frequency (e.g., the frequency of the power transfer device output), and further, the control scheme may utilize a continuously variable adjustment to pulse widths.

When the present invention is implemented in a power transfer device, it enhances the response of the power transfer device to changing harmonic loads by allowing a collection of comparative waveforms, each one responsive to different harmonic load requirements, to be designed, analyzed, stored, and modified or selected by a feedback circuit within a particular power transfer device.

The present invention also enhances the capability of circuit designers to design an ideal waveform by supporting the investigation of many algorithms, both formal and informal, in order to create the appearance of stochastic frequency signatures in the comparative waveform. Such algorithms can include a circular series of offsets created by a series of hand-selected numbers, or an algorithm that includes a series of numeric offsets created by a modulo operation on a hand-selected base number, or algorithms having a series of balanced offsets (i.e., large and small, or early and late), and algorithms having a series of numbers selected from a tested collection of multiple lists created by repeating the results of a programmed numeric processor providing randomly generated lists of numbers, wherein, in each case above, the offsets and lists of numbers are subsequently used to define the transition times of a comparative waveform.

The present invention in another implementation enhances the capability of circuit designers to design an ideal PWM control waveform by supporting the investigation of sophisticated power transfer algorithms in order to create the appearance of stochastic frequency signatures and, at the same time, minimize the residual energy found in the lower numbered harmonics of the power transfer waveform as controlled by the comparative waveform. Sophisticated power transfer algorithms include a displacement algorithm wherein each individual pulse is moved in time and then adjusted in duration to minimize its impact on lower numbered harmonics, a paired pulse displacement algorithm wherein two individual pulses are moved in time and then one pulse of the two is adjusted in duration to minimize the combined impact on lower numbered harmonics, a power transfer algorithm having combinations where one or more pulses are subjected to a displacement algorithm with a correction pulse in a series of pulses where each group may independently include one or more pulses.

The present invention also provides, in part, the ability to enhance the capability of circuit designers to design an ideal PWM control waveform by supporting the investigation of sophisticated power transfer algorithms in order to create the appearance of stochastic frequency signatures and, at the same time, minimize the residual energy found in the lower numbered harmonics of the power transfer waveform as controlled by the comparative waveform. This investigation includes investigation into the timing characteristics defined by the orthogonal relationships of lower numbered harmonics, especially harmonics that a circuit designer is trying to eliminate, investigating refinement of the comparative waveform master clock frequency (e.g., defining the requirements of the Time Mark shown in FIG. 5) by analyzing the frequency requirement of the uppermost two or uppermost three harmonics from the set of harmonics that a circuit designer is trying to eliminate, investigation of non-uniform time division assignment based on overlaying harmonic signals, and investigation that involves detailed analysis of changes made to comparative signals by hand-selecting bits (e.g., hand selecting state values). In each case, the investigation is facilitated as a study of patterns and detailed analysis (not in real time) and as the study of applied patterns to test specific cases in power transfer devices in laboratory conditions (in real time).

The implementation of the present invention enhances the capability of circuit designers to apply waveform improvements to a broad range of circumstances requiring adjustment of the fundamental frequency of the power transfer waveform. These circumstances include maintaining a fundamental PWM frequency based on power transfer device filtering design limitations and storing multiple images of the comparative waveform (aka multiple signal replicas) such that each may be selected and smoothly modified within the limitations of a master clock Time Mark. These circumstances can also include maintaining a PWM pattern (a patterned comparative waveform) such that the patterned signal (aka signal replica) may be smoothly modified by varying the time basis of the master time clock thereby maintaining the same number of Time Marks during each fundamental frequency cycle even as the fundamental frequency varies.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A method for generating a pulse width modulation (PWM) control signal for a power transfer device, comprising:
providing a PWM signal having a stochastic characteristic; and
transforming the PWM signal to include control information.

2. The method of claim 1 wherein providing the PWM signal comprises providing a digital or analog reference signal having a stochastic characteristic and using the reference signal to provide the PWM signal with stochastic characteristics.

3. The method of claim 1 wherein transforming the PWM signal to include control information comprises encoding the control information to define a desired output of the power transfer device.

4. The method of claim 1 wherein the PWM signal is transformed so as not to lose the stochastic characteristic.

5. The method of claim 1, comprising storing the transformed PWM signal in a digital storage device.

6. The method of claim 5 wherein the stored PWM signal exhibits at least one from among the frequency domain characteristics of distributing one or more discrete frequency component energy among two or more discrete frequency components, distributing one or more discrete frequency component energy across portions of the continuous spectrum, distributing one or more peak densities of frequency energy from narrow segments of the continuous spectrum to wider segments of the continuous spectrum, redistributing frequency energy to segments of the frequency spectrum avoiding those portions of the spectrum that are associated with problems for power transfer devices, redistributing frequency energy and reshaping the final output waveform to intentionally compensate for pre-defined or desired harmonic components that are associated with desirable output characteristics for power transfer devices.

7. The method of claim 5 wherein the stored PWM signal is configured to minimize at least one parameter from among harmonic signatures, is configured to minimize audible noise from the power transfer device, is configured to minimize component vibration in the power transfer device, is configured to reduce unnecessary switching events, is configured to reduce audible noise in power utilization equipment connected to the power transfer device, is configured to minimize component vibration in power utilization equipment connected to the power transfer device, or is configured to reduce frequency-domain energy peaks from current components in the power transfer device.

8. The method of claim 2, comprising at least one additional transformation of the transformed PWM signal performed by a digital processing system.

9. The method of claim 2 wherein the transformed PWM signal comprises deterministic frequency signatures and stochastic frequency signatures exhibited in the frequency domain.

10. The method of claim 2, comprising inputting the reference signal into a comparator to provide the PWM signal with the stochastic characteristic.

11. The method of claim 2, further comprising storing the reference signal in a digital memory device prior to providing the digital PWM signal.

12. The method of claim 11 wherein providing the digital reference signal comprises providing the digital reference signal with at least one from among the frequency domain characteristics of distributing one or more discrete frequency component energy among two or more discrete frequency components, distributing one or more discrete frequency component energy across portions of the continuous spectrum, distributing one or more peak densities of frequency energy from narrow segments of the continuous spectrum to wider segments of the continuous spectrum, redistributing frequency energy to segments of the frequency spectrum avoiding those portions of the spectrum that are associated with problems for power transfer devices, redistributing frequency energy and reshaping the final output waveform to intentionally compensate for pre-defined or desired harmonic components that are associated with desirable output characteristics for power transfer devices.

13. The method of claim 11 wherein the stored reference signal is configured to minimize at least one parameter from among harmonic signatures, is configured to minimize audible noise from the power transfer device, is configured to minimize component vibration in the power transfer device, is configured to reduce unnecessary switching events, is configured to reduce audible noise in power utilization equipment connected to the power transfer device, is configured to minimize component vibration in power utilization equipment connected to the power transfer device, or is configured to reduce frequency-domain energy peaks from current components in the power transfer device.

14. A method of generating a digital pulse width modulation (PWM) control signal for a power transfer device that does not require feedback, comprising:
providing a digital reference signal having a stochastic characteristic and using the reference signal to provide a digital PWM signal with stochastic characteristics for controlling the power transfer device and without providing control information in the digital PWM signal.

15. The method of claim 14, comprising storing the digital PWM signal in a digital storage device.

16. The method of claim 15 wherein the stored digital PWM signal exhibits at least one from among the frequency domain characteristics of distributing one or more discrete frequency component energy among two or more discrete frequency components, distributing one or more discrete frequency component energy across portions of the continuous spectrum, distributing one or more peak densities of frequency energy from narrow segments of the continuous spectrum to wider segments of the continuous spectrum, redistributing frequency energy to segments of the frequency spectrum avoiding those portions of the spectrum that are associated with problems for power transfer devices, redistributing frequency energy and reshaping the final output waveform to intentionally compensate for pre-defined or desired harmonic components that are associated with desirable output characteristics for power transfer devices.

17. The method of claim 14, further comprising storing the digital reference signal in a digital memory device prior to providing the digital PWM signal.

18. The method of claim 17 wherein providing the digital reference signal comprises providing the digital reference signal with at least one from among the frequency domain characteristics of distributing one or more discrete frequency component energy among two or more discrete frequency components, distributing one or more discrete frequency component energy across portions of the continuous spectrum, distributing one or more peak densities of frequency energy from narrow segments of the continuous spectrum to wider segments of the continuous spectrum, redistributing frequency energy to segments of the frequency spectrum avoiding those portions of the spectrum that are associated with problems for power transfer devices, redistributing frequency energy and reshaping the final output waveform to intentionally compensate for pre-defined or desired harmonic components that are associated with desirable output characteristics for power transfer devices.

19. The method of claim 17 wherein the stored digital reference signal is configured to minimize at least one parameter from among harmonic signatures, is configured to minimize audible noise from the power transfer device, is configured to minimize component vibration in the power transfer device, is configured to reduce unnecessary switching events, is configured to reduce audible noise in power utilization equipment connected to the power transfer device, is configured to minimize component vibration in power utilization equipment connected to the power transfer device, or is configured to reduce frequency-domain energy peaks from current components in the power transfer device.

20. A circuit, comprising:
means for generating a digital pulse width modulation (PWM) control signal for a power transfer device, comprising:
means for providing a digital PWM signal having a stochastic characteristic; and
means for transforming the digital PWM signal to include control information.

21. The circuit of claim 20 wherein the means for providing the PWM signal comprises a circuit for providing a digital reference signal having a stochastic characteristic and a circuit for using the reference signal to provide the PWM signal with stochastic characteristics.

22. The circuit of claim 20 wherein the means for transforming the PWM signal to include control information comprises a digital processing circuit for encoding the control information to define a desired output of the power transfer device.

23. The circuit of claim 20 wherein the means for transforming the PWM signal is adapted to transform the PWM signal so as not to lose the stochastic characteristic.

24. The circuit of claim 20, further comprising a digital storage device for storing the transformed digital PWM signal

25. The circuit of claim 24 wherein the stored transformed digital PWM signal exhibits at least one from among the frequency domain characteristics of distributing one or more discrete frequency component energy among two or more discrete frequency components, distributing one or more discrete frequency component energy across portions of the continuous spectrum, distributing one or more peak densities of frequency energy from narrow segments of the continuous spectrum to wider segments of the continuous spectrum, redistributing frequency energy to segments of the frequency spectrum avoiding those portions of the spectrum that are associated with problems for power transfer devices, redistributing frequency energy and reshaping the final output waveform to intentionally compensate for pre-defined or desired harmonic components that are associated with desirable output characteristics for power transfer devices.

26. The circuit of claim 24 wherein the stored transformed PWM signal is configured to minimize at least one parameter from among harmonic signatures, is configured to minimize audible noise from the power transfer device, is configured to minimize component vibration in the power transfer device, is configured to reduce unnecessary switching events, is configured to reduce audible noise in power utilization equipment connected to the power transfer device, is configured to minimize component vibration in power utilization equipment connected to the power transfer device, or is configured to reduce frequency-domain energy peaks from current components in the power transfer device.

27. The circuit of claim 21, comprising at least one additional means for performing an additional digital transformation of the transformed PWM signal.

28. The circuit of claim 21 wherein the means for transforming the digital PWM signal is adapted to transform the digital PWM signal to comprise deterministic frequency signatures and stochastic frequency signatures exhibited in the frequency domain.

29. The circuit of claim 21, further comprising a digital storage circuit adapted to store the reference signal prior to providing the digital PWM signal.

30. The circuit of claim 29 wherein the means for providing the digital reference signal comprises a circuit adapted to provide the digital reference signal with at least one from among the frequency domain characteristics of distributing one or more discrete frequency component energy among two or more discrete frequency components, distributing one or more discrete frequency component energy across portions of the continuous spectrum, distributing one or more peak densities of frequency energy from narrow segments of the continuous spectrum to wider segments of the continuous spectrum, redistributing frequency energy to segments of the frequency spectrum avoiding those portions of the spectrum that are associated with problems for power transfer devices, redistributing frequency energy and reshaping the final output waveform to intentionally compensate for pre-defined or desired harmonic components that are associated with desirable output characteristics for power transfer devices.

31. The circuit of claim 29 wherein the stored reference signal is configured to minimize at least one parameter from among harmonic signatures, is configured to minimize audible noise from the power transfer device, is configured to minimize component vibration in the power transfer device, is configured to reduce unnecessary switching events, is configured to reduce audible noise in power utilization equipment connected to the power transfer device, is configured to minimize component vibration in power utilization equipment connected to the power transfer device, or is configured to reduce frequency-domain energy peaks from current components in the power transfer device.

32. A circuit, comprising:
means for generating a digital pulse width modulation (PWM) control signal for a power transfer device that does not require feedback, comprising:
a circuit that provides a digital reference signal having a stochastic characteristic; and
a circuit that uses the reference signal to provide a digital PWM signal with stochastic characteristics for controlling the power transfer device in which the digital PWM signal has no control information.
